(19) United States
(12) Patent Application Publication
(10) Pub. No.: US 2018/0261178 A1
(43) Pub. Date: Sep. 13, 2018

(54) Shift Register with Fault Tolerance Mechanism and Driving Method Thereof, and Gate Driving Circuit

(71) Applicants: BOE Technology Group Co., Ltd., Beijing (CN); Hefei BOE Optoelectronics Technology Co., Ltd., Hefei (CN)

(72) Inventors: Xianjie Shao, Beijing (CN); Junsheng Chen, Beijing (CN)

(21) Appl. No.: 15/801,570

(22) Filed: Nov. 2, 2017

(30) Foreign Application Priority Data
Mar. 7, 2017 (CN) 201710132394.X

(51) Int. Cl. G09G 3/36; H03K 17/687

(52) U.S. Cl. CPC G09G 3/3677; G09G 2310/0286; H03K 17/6871

(57) ABSTRACT

Provided are a shift register and a gate driving circuit. The shift register includes: a pull-up driving circuit connected to an input signal terminal, a first voltage terminal and a pull-up node; a pull-up circuit connected to a clock signal terminal, the pull-up node and an output terminal; a pull-down driving circuit connected to a second voltage terminal, a third voltage terminal, the pull-up node and a pull-down node; a pull-down circuit connected to the second voltage terminal, the pull-down node, the pull-up node and the output terminal; and an interference removing circuit connected to an interference removing signal terminal and the pull-down node, and configured to transmit an active interference removing signal to the pull-down node to charge the pull-down node when an interference removing signal outputted at the interference removing signal terminal is at an active control level.

### CROSS-REFERENCES TO RELATED APPLICATIONS

This application claims priority to and the benefit of Chinese Patent Application No. 201710132394.X filed on Mar. 7, 2017, which application is incorporated herein in its entirety.

### TECHNICAL FIELD

The present disclosure relates to a shift register design with low noise and high reliability for a bi-directional scan driver of a liquid crystal display, and more particularly to a shift register having a fault tolerance mechanism and a driving method thereof, a gate driving circuit and a display.

### BACKGROUND

Liquid crystal display panel makes displaying by adopting a progressive scan matrix with M×N dots being arranged. TFT-LCD (Thin Film Transistor-Liquid Crystal Display) driver mainly includes a gate driver and a data driver, wherein the gate driver converts an inputted clock signal through a shift register and applies the converted signal to a gate line of the liquid crystal display panel.

Shift register is commonly used in a gate driver of a liquid crystal display panel, and each gate line is docked to a circuit stage of the shift register. Gate input signals are outputted through the gate driver, and pixels are scanned progressively. The gate driver may be provided in a display panel in the encapsulated form of COF (Chip On Film) or COG (Chip On Glass), or may be formed in the display panel with an integrated circuit unit being constituted by TFT. For the liquid crystal display panel, GOA (Gate Driver on Array) design of the gate driver can reduce product cost, also subtract a process and improve production capacity.

The present disclosure provides a new design of shift register for gate driving of the liquid crystal display. The shift register can quickly perform global reset when the output signal of the circuit is abnormal.

### SUMMARY

Parts of additional aspects and advantages of the present disclosure will be set forth in the description which follows, and parts of them will be obvious from the description, or may be learned in practice of the present disclosure.

The present disclosure is directed to the design of a shift register having a fault tolerance mechanism and a high reliability and applicable to a scan driver of a liquid crystal display.

The present disclosure relates to a design method of a shift register for gate scanning of a liquid crystal display, the shift register can quickly perform global reset when the output signal of the circuit is abnormal. The shift register comprises: a pull-up circuit for outputting a driving signal to an output terminal OUTPUT according to a high-level signal at an input signal terminal INPUT and a clock signal terminal CLK or CLKB; a reset circuit for outputting an OFF signal to the pull-up node PU through a reset signal RESET, that is, an output terminal from a shift register in a next stage; and a pull-down circuit for implementing de-noising on the pull-up node PU and the output terminal OUTPUT through a signal inputted from the pull-down node PD and the control circuit. In a gate driving circuit, an input signal INPUT of the circuit in each stage is an output signal OUTPUT in a previous stage; the reset signal RESET of the circuit in each stage is an output signal OUTPUT of a next stage. The most important is that an interference removing circuit that uses the interference removing signal GLB to control is added, thereby the global reset function is achieved.

The present disclosure provides a shift register, comprising: a pull-up driving circuit connected to an input signal terminal, a first voltage terminal and a pull-up node, and configured to output a voltage signal of the first voltage terminal to the pull-up node when an input signal of the input signal terminal is at an active input level; a pull-up circuit connected to a clock signal terminal, the pull-up node and an output terminal, and configured to output a clock signal of the clock signal terminal to the output terminal when a pull-up signal of the pull-up node is at an active pull-up level; a pull-down driving circuit connected to a second voltage terminal, a third voltage terminal, the pull-up node and a pull-down node, and configured to control a potential at the pull-down node; a pull-down circuit connected to the second voltage terminal, the pull-down node, the pull-up node and the output terminal, and configured to pull down the output terminal and the pull-up node to a voltage signal of the second voltage terminal when a pull-down signal of the pull-down node is at an active pull-down level; and an interference removing circuit connected to an interference removing signal terminal and the pull-down node, and configured to transmit an active interference removing signal to the pull-down node to charge the pull-down node when an interference removing signal outputted at the interference removing signal terminal is at an active control level.

The present disclosure further provides a gate driving circuit comprising N cascaded shift registers as described above, N being a natural number, wherein the input signal terminal of the shift register in a first stage is connected to a frame start signal terminal, and the reset signal terminal of the shift register in the first stage is connected to the output terminal of the shift register in a next stage, the input signal terminal of the shift register in a last stage is connected to the output terminal of the shift register in a previous stage, the reset signal terminal of the shift register in the last stage is connected to the frame start signal terminal, as for the shift register other than the shift register in the first stage and the shift register in the last stage, the input signal terminal thereof is connected to the output terminal of the shift register in a previous stage, and the reset signal thereof is connected to the output terminal of the shift register in a next stage, in the gate driving circuit, the interference removing signal is connected to the shift register in each stage.

The present disclosure further provides a display device comprising the gate driving circuit as described above.

The present disclosure further provides a driving method for a shift register, the method comprising: in a first period, the pull-up driving circuit outputs the voltage signal of the first voltage terminal to the pull-up node and charges a storage circuit under control of a signal inputted at the input signal terminal, so that the pull-up circuit outputs the clock signal of the clock signal terminal to the output terminal; since the voltage signal of the first voltage terminal is outputted to the pull-up node, the pull-down driving circuit pulls down the pull-down node to the voltage signal of the second voltage terminal, so that the pull-down circuit does not operate; in a second period, the pull-up driving circuit does not operate under control of the signal inputted at the input signal terminal, and the pull-up node continues to maintain the voltage signal of the first voltage terminal; the pull-up circuit remains in an operating state, and the clock signal is outputted to the output terminal by the pull-up circuit; the pull-up node is still at the voltage signal of the first voltage terminal, and the pull-down node is discharged by the pull-down driving circuit, so that the pull-down circuit continues to remain in the non-operating state; in a third period, the reset circuit operates to pull down the pull-up signal at the pull-up node to the voltage signal at the second voltage terminal under control of the reset signal inputted by the reset signal terminal; since the pull-up node is at the voltage signal of the second voltage terminal, the pull-up circuit does not operate; in a fourth period, the pull-down driving circuit outputs the voltage signal of the third voltage terminal to the pull-down node under control of the voltage signal of the third voltage terminal; when a voltage at the pull-down node is the voltage signal of the third voltage terminal, the pull-down circuit operates to pull down the pull-up node and the output terminal to the voltage signal of the second voltage terminal, so as to de-noise the pull-up node and the output terminal; and in a fifth period, when one frame ends and before a next frame arrives, with the interference removing signal at an active level, the interference removing circuit operates to charge the pull-down node.

### BRIEF DESCRIPTION OF THE DRAWINGS

The above and other objects, features and advantages of the present disclosure will become more apparent from the following detailed description of the preferred embodiments of the present disclosure as provided in conjunction with the accompanying drawings in which like reference numerals indicate elements of like structures:

FIG. 1 shows a block diagram of an exemplary circuit configuration of a shift register according to an embodiment of the present disclosure;

FIG. 2 shows an exemplary circuit configuration diagram of a shift register according to an embodiment of the present disclosure;

FIG. 3 shows a first schematic diagram of a gate driving circuit formed by cascading a plurality of shift registers according to an embodiment of the present disclosure;

FIG. 4 shows a second schematic diagram of a gate driving circuit formed by cascading a plurality of shift registers according to an embodiment of the present disclosure;

FIG. 5 shows a timing diagram of scanning of a shift register according to an embodiment of the present disclosure; and

FIG. 6 shows a flow chart of a driving method for a shift register according to an embodiment of the present disclosure.

### DETAILED DESCRIPTION OF THE EMBODIMENTS

Hereinafter, the present disclosure will be described fully with reference to the accompanying drawings that illustrate the embodiments of the present disclosure. However, the present disclosure may be implemented in many different forms and should not be construed as limited to the embodiments described herein. Contrarily, these embodiments are provided to make the present disclosure be thorough and complete, and to fully convey the scope of the present disclosure to those skilled in the art. In the drawings, the components are enlarged for clarity.

Each of the transistors adopted in all of the embodiments of the present disclosure may be a thin film transistor or an FET (Field Effect Transistor), or other devices of the same properties. In the embodiments of the present disclosure, connection of a source and a drain of each transistor may be interchanged, the source and the drain of each transistor in the embodiments of the present disclosure have no difference practically. Here, in order to distinguish the two electrodes other than the gate, one electrode is referred to as a drain, and the other electrode is referred to as a source.

For the purpose of facilitating further understanding of the present disclosure, the present disclosure will now be described in detail with reference to the accompanying drawings.

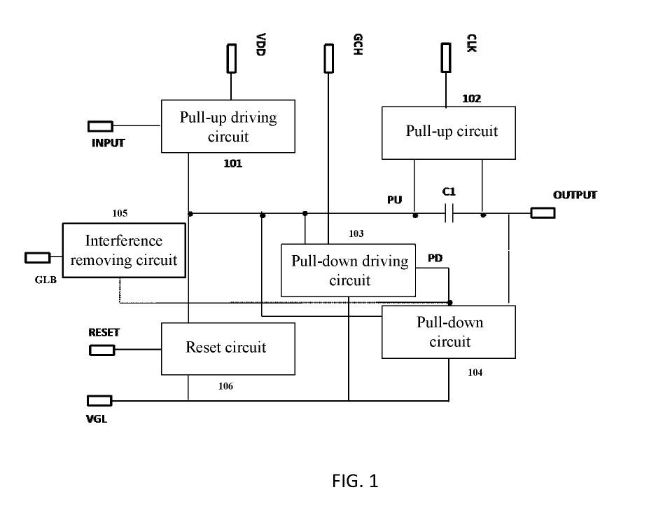

FIG. 1 shows a block diagram of an exemplary circuit configuration of a shift register according to an embodiment of the present disclosure.

The shift register shown in FIG. 1 comprises a pull-up driving circuit 101, a pull-up circuit 102, a pull-down driving circuit 103, a pull-down circuit 104, and an interference removing circuit 105.

The pull-up driving circuit 101 is connected to an input signal terminal INPUT, a first voltage terminal VDD and a pull-up node PU, and configured to output a voltage signal of the first voltage terminal VDD to the pull-up node PU when an input signal of the input signal terminal INPUT is at an active input level.

The pull-up circuit 102 is connected to a clock signal terminal CLK, the pull-up node PU and an output terminal OUTPUT, and configured to output a clock signal of the clock signal terminal CLK to the output terminal OUTPUT when a pull-up signal of the pull-up node PU is at an active pull-up level.

The pull-down driving circuit 103 is connected to a second voltage terminal VGL, a third voltage terminal GCH, the pull-up node PU and a pull-down node PD, and configured to control a potential at the pull-down node PD. For example, when the pull-up signal at the pull-up node PU is at an active pull-up level, the pull-down driving circuit 103 generates a pull-down signal at an inactive pull-down level at the pull-down node PD; when the pull-up signal at the pull-up node PU is at an inactive pull-up level, the pull-down driving circuit 103 supplies a voltage signal at the third voltage terminal GCH to the pull-down node PD in response to the voltage signal at the third voltage terminal GCH.

The pull-down circuit 104 is connected to the second voltage terminal VGL, the pull-down node PD, the pull-up node PU and the output terminal OUTPUT, and configured to pull down the output terminal OUTPUT and the pull-up node PU to a voltage signal of the second voltage terminal VGL when a pull-down signal of the pull-down node PD is at an active pull-down level.

The interference removing circuit 105 is connected to an interference removing signal terminal GLB and the pull-down node PD, and configured to transmit an active interference removing signal GLB to the pull-down node PD to charge the pull-down node PD when the interference removing signal GLB at the interference removing signal terminal is at an active control level.

The interference removing signal GLB is provided with an active control level after abnormity occurs to an output signal of the shift register and before a next frame signal arrives.

The interference removing signal may be a frame start signal STV or a control signal CTR.

The first voltage terminal VDD and the third voltage terminal GCH are a high voltage terminal each, the second voltage terminal VGL is a low voltage terminal.

In the embodiment of the present disclosure, the shift register is additionally provided with the interference removing circuit 105 controlled through the interference removing signal GLB, a level of the pull-down node PD is controlled by the interference removing circuit 105. When GLB is at a high level, the pull-down node PD also is at a high level, so that the pull-down circuit 104 will begin to operate and discharge the pull-up node PU and the output terminal OUTPUT.

The shift register according to an embodiment of the present disclosure may further comprise a storage circuit C1. A first terminal of the storage circuit C1 is connected to the pull-up node PU and a second terminal of the storage circuit C1 is connected to the output terminal OUTPUT, and the storage circuit C1 is configured to be charged when the voltage signal of the first voltage terminal is outputted to the pull-up node PU.

The shift register according to an embodiment of the present disclosure may further comprise a reset circuit 106. The reset circuit 106 is connected to a reset signal terminal RESET, the second voltage terminal VGL and the pull-up node PU, and configured to pull down the pull-up signal of the pull-up node PU to the voltage signal of the second voltage terminal VGL when a reset signal at the reset signal terminal RESET is at an active control level.

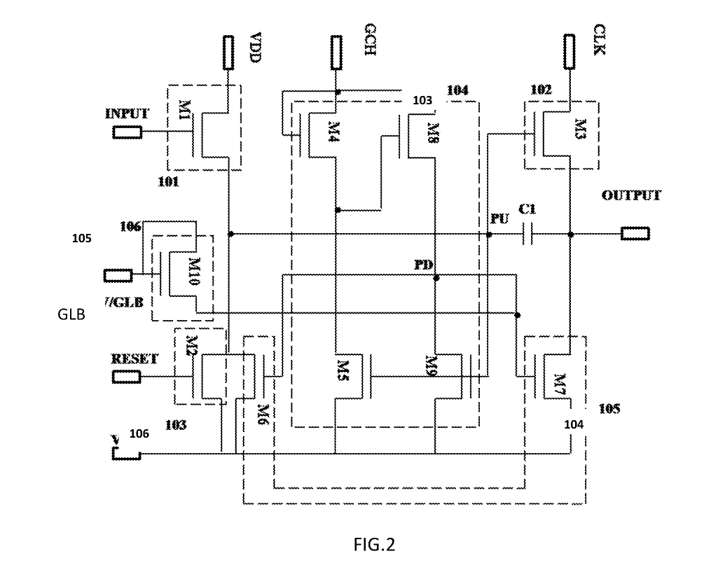

FIG. 2 shows an exemplary circuit configuration diagram of a shift register according to an embodiment of the present disclosure.

FIG. 2 is a circuit diagram of a specific implementation of FIG. 1, including TFT transistors M1 to M10 and a capacitor C1. Next, description is provided with each of the transistors in FIG. 2 being an N-type transistor which is turned on when a high level is inputted at the gate thereof as an example.

As shown in FIG. 2, in an embodiment, for example, the pull-up driving circuit 101 comprises a pull-up driving transistor M1. A gate of the pull-up driving transistor M1 is connected to the input signal terminal INPUT, a first electrode of the pull-up driving transistor M1 is connected to the first voltage terminal VDD, and a second electrode of the pull-up driving transistor M1 is connected to the pull-up node PU. When the input signal at the input signal terminal INPUT is at a high level, the pull-up driving transistor M1 is turned on and the voltage signal at the first voltage terminal VDD is outputted to the pull-up node PU.

In an embodiment, the pull-up circuit 102 comprises an output transistor M3. A gate of the output transistor M3 is connected to the pull-up node PU, a first electrode of the output transistor M3 is connected to the clock signal terminal CLK, and a second electrode of the output transistor M3 is connected to the output terminal OUTPUT. When the pull-up signal at the pull-up node PU is at a high level, the output transistor M3 is turned on, and the clock signal at the clock signal terminal CLK is outputted to the output terminal OUTPUT.

In an embodiment, for example, the pull-down driving circuit 103 comprises a first pull-down driving transistor M8, a second pull-down driving transistor M9, a third pull-down driving transistor M4 and a fourth pull-down driving transistor M5. A gate of the first pull-down driving transistor M8 is connected to a second electrode of the third pull-down driving transistor M4, a first electrode of the first pull-down driving transistor M8 is connected to the third voltage terminal GCH, and a second electrode of the first pull-down driving transistor M8 is connected to the pull-down node PD; a gate of the second pull-down driving transistor M9 is connected to the pull-up node PU, a first electrode of the second pull-down driving transistor M9 is connected to the pull-down node PD, and a second electrode of the second pull-down driving transistor M9 is connected to the second voltage terminal VGL; a gate and a first electrode of the third pull-down driving transistor M4 are connected to the third voltage terminal GCH; a gate of the fourth pull-down driving transistor M5 is connected to the pull-up node PU, a first electrode of the fourth pull-down driving transistor M5 is connected to the second electrode of the third pull-down driving transistor M4, and a second electrode of the fourth pull-down driving transistor M5 is connected to the second voltage terminal VGL.

In an embodiment, for example, the pull-down circuit 104 comprises a node pull-down transistor M6 and an output pull-down transistor M7. A gate of the node pull-down transistor M6 and a gate of the output pull-down transistor M7 are connected to the pull-down node PD, a first electrode of the node pull-down transistor M6 is connected to the pull-up node PU, a first electrode of the output pull-down transistor M7 is connected to the output terminal OUTPUT, a second electrode of the node pull-down transistor M6 and a second electrode of the output pull-down transistor M7 are connected to the second voltage terminal VGL. When the pull-down signal at the pull-down node PD is at a high level, the node pull-down transistor M6 and the output pull-down transistor M7 are turned on, so as to pull down the pull-up node PU and the output terminal OUTPUT to the voltage signal at the second voltage terminal VGL, respectively.

In an embodiment, for example, the interference removing circuit 105 comprises an interference removing transistor M10. A gate and a first electrode of the interference removing transistor M10 are both connected to the interference removing signal terminal GLB, and a second electrode of the interference removing transistor M10 is connected to the pull-down node PD.

In an embodiment, for example, the storage circuit comprises a capacitor C1, a first terminal of the capacitor C1 is connected to the pull-up node PU, and a second terminal of the capacitor C1 is connected to the output terminal OUTPUT. When the pull-up driving transistor M1 is turned on, the capacitor C1 is charged by the high-level signal of the first voltage terminal VDD.

In an embodiment, for example, the reset circuit 106 comprises a reset transistor M2. A gate of the reset transistor M2 is connected to the reset signal terminal RESET, a first electrode of the reset transistor M2 is connected to the pull-up node PU, and a second electrode of the reset transistor M2 is connected to the second voltage terminal VGL. The reset transistor M2 is turned on when the reset signal at the reset signal terminal RESET is at a high level, so that the pull-up signal at the pull-up node PU is pulled down to the voltage signal of the second voltage terminal VGL.

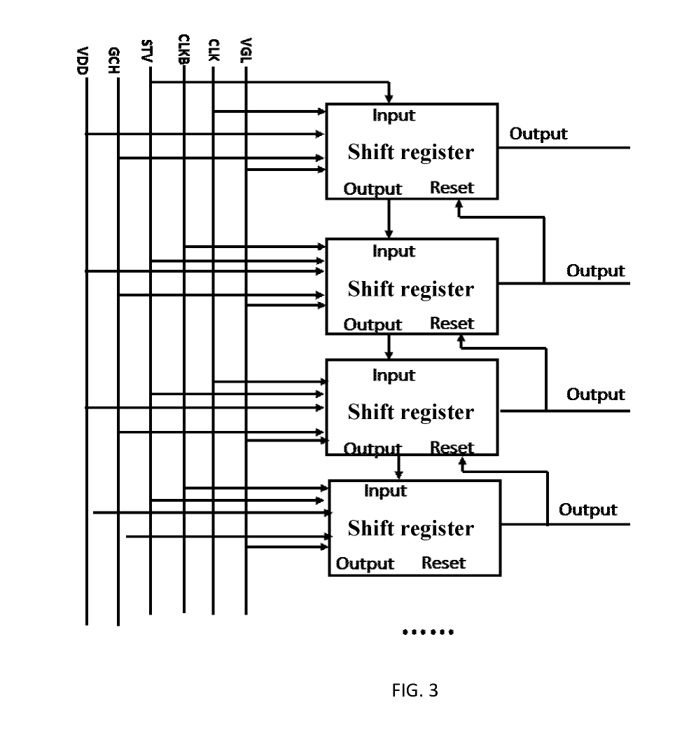

FIG. 3 shows a first schematic diagram of a gate driving circuit formed by cascading a plurality of shift registers according to an embodiment of the present disclosure.

The gate driving circuit shown in FIG. 3 comprises a plurality of cascaded shift registers. The shift register in each stage may be constructed by using the structure described below.

The input signal terminal of the shift register in a first stage is connected to a frame start signal terminal, a start signal at the frame start signal terminal is a pulse signal for activating the shift register, optionally, such as the frame start signal STV, and the reset signal terminal of the shift register in the first stage is connected to the output terminal of the shift register in a next stage.

The input signal terminal of the shift register in a last stage is connected to the output terminal of the shift register in a previous stage, and the reset signal terminal of the shift register in the last stage is connected to the frame start signal terminal STV.

As for the shift register other than the shift register in the first stage and the shift register in the last stage, the input signal terminal thereof is connected to the output terminal of the shift register in a previous stage, and the reset signal thereof is connected to the output terminal of the shift register in a next stage. All cascaded shift registers can adopt the shift register shown in FIGS. 1 and 2.

As shown in FIG. 3, in the gate driving circuit of the present application, the frame start signal STV is connected, as the interference removing signal GLB, to the shift register in each stage, so that after abnormality occurs to the output signal of the shift register, an active control level is supplied before a next frame signal arrives, so as to globally reset all shift registers.

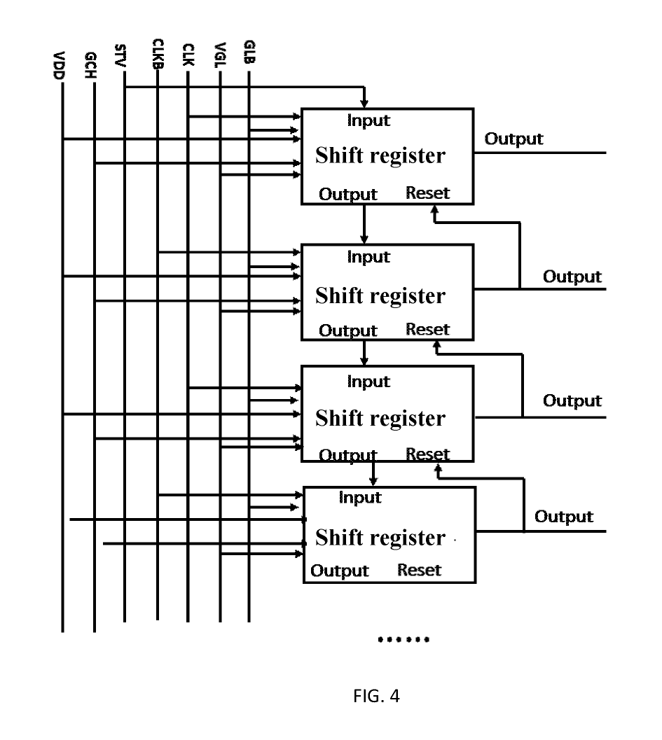

FIG. 4 shows a second schematic diagram of a gate driving circuit formed by cascading a plurality of shift registers according to an embodiment of the present disclosure.

The gate driving circuit shown in FIG. 4 comprises a plurality of cascaded shift registers. The shift register in each stage may be constructed by using the structure described below.

The input signal terminal of the shift register in a first stage is connected to a frame start signal terminal, a start signal at the frame start signal terminal is a pulse signal for activating the shift register, optionally, such as the frame start signal STV, and the reset signal terminal of the shift register in the first stage is connected to the output terminal of the shift register in a next stage.

The input signal terminal of the shift register in a last stage is connected to the output terminal of the shift register in a previous stage, and the reset signal terminal of the shift register in the last stage is connected to the frame start signal terminal STV.

As for the shift register other than the shift register in the first stage and the shift register in the last stage, the input signal terminal thereof is connected to the output terminal of the shift register in a previous stage, and the reset signal thereof is connected to the output terminal of the shift register in a next stage. All cascaded shift registers can adopt the shift register shown in FIGS. 1 and 2.

As shown in FIG. 4, in the gate driving circuit of the present application, one control signal CTR is added as the interference removing signal GLB to be connected to the shift register in each stage, so that after abnormality occurs to the output signal of the shift register, an active control level is supplied before a next frame signal arrives, so as to globally reset all shift registers.

The two schemes in FIGS. 3 and 4 both are performing global reset on all the registers after the output signal becomes disordered and before a next frame signal arrives.

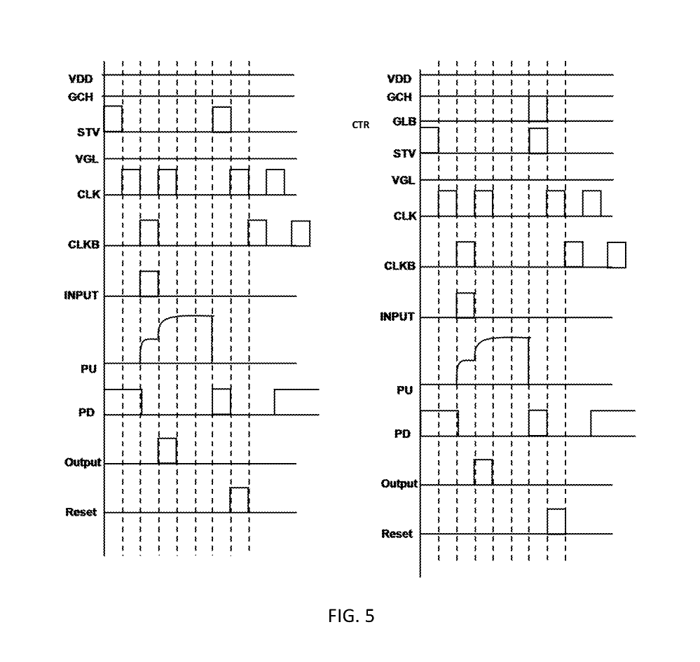

FIG. 5 shows a timing diagram of scanning of a shift register according to an embodiment of the present disclosure.

FIG. 5 is a timing diagram of the two schemes shown in FIGS. 3 and 4 of the present disclosure. When the output signal is normal, the shift register operates normally, and the interference removing circuit 105 operates when the interference removing signal GLB (i.e., STV or CTR) is at a high level, it does not affect the normal operating state.

In a first period, the input signal terminal INPUT has a high-level signal, so that the pull-up driving transistor M1 is turned on; the high-level signal of the first voltage terminal VDD charges the capacitor C1, at this moment, a level at the pull-up node PU is pulled up, so that the output transistor M3 is turned on, in this case, the clock signal at the clock signal terminal CLK is at a low level, the output terminal OUTPUT outputs a low level. Further, since the pull-up node PU is at a high level, the second pull-down driving transistor M9 and the fourth pull-down driving transistor M5 are turned on, so that the pull-down node PD is at a low level, consequently, the node pull-down transistor M6 and the output pull-down transistor M7 are turned off. In addition, in this period, the reset signal at the reset signal terminal RESET is at a low level, and the reset transistor M2 is turned off. Thereby, stability of signal output is ensured.

In a second period, when the input signal terminal INPUT is at a low level, the pull-up driving transistor M1 is turned off, the pull-up node PU continues to remain a high level, and the output transistor M3 remains a turned-on state. The reset signal terminal RESET is at a low level and the reset transistor M2 remains turned-off. At this moment, the clock signal at the clock signal terminal CLK is at a high level, in this case, the high level of the clock signal is outputted to the output terminal, and the voltage at the pull-up node PU is raised because of bootstrapping effect of the capacitor C1. At this moment, the pull-up node PU is still at a high level, and the second pull-down driving transistor M9 and the fourth pull-down driving transistor M5 remain turned-on to discharge the pull-down node PD, so that the node pull-down transistor M6 and the output pull-down transistor M7 continue to remain turned-off. Thereby, stability of signal output is ensured.

In a third period, the input signal terminal INPUT is at a low level, the input transistor M1 remains turned-off. When the reset signal at the reset terminal RESET is a high-level signal (the reset signal is the output of the shift register in a next stage), the high-level signal at the reset signal terminal causes the reset transistor M2 to be turned on, the pull-up signal at the pull-up node PU is pulled down to the voltage signal at the second voltage terminal VGL. Since the pull-up node PU is at a low level, the output transistor M3 is turned off.

In a fourth period, the clock signal terminal CLK is at a high level, the clock signal at CLKB is at a low level, and the third voltage terminal GCH has a high-level voltage signal. At this moment, the third pull-down driving transistor M4 is turned on, since the pull-up node PU is discharged by the reset transistor M2 in the previous period, in this case, the second pull-down driving transistor M9 and the fourth pull-down driving transistor M5 are in a turned-off state. In this case, the first pull-down driving transistor M8 is turned on to charge the pull-down node PD; at this moment, a level at the pull-down node PD is pulled up, so as to turn on the node pull-down transistor M6 and the output pull-down transistor M7, such that the pull-up node PU and output terminal OUTPUT are pull down to the voltage signal at the second voltage terminal VGL and the pull-up node PU and the output terminal OUTPUT are de-noised. As a result, a coupling noise voltage generated by the clock signal terminal CLK can be eliminated, thereby low voltage output is ensured, and stability of signal output is ensured. As long as the pull-up node PU is at a high level (the pull-up node PU in a current stage is charged), the pull-down node PD is at a low level; as long as the pull-up node PU is at a low level, the pull-down node PD is always at a high level, the node pull-down transistor M6 and the output pull-down transistor M7 are always turned on, so as to de-noise the pull-up node PU and the output terminal OUTPUT.

In a fifth period, when one frame ends and before a next frame arrives, the interference removing signal GLB (i.e., STV or CTR) is an active control signal, thereby the interference removing transistor M10 is turned on, and the interference removing transistor M10 charges the pull-down node PD, the pull-down node PD is at a high level, which will de-noise the pull-up node PU, thus avoiding bad effects due to charge accumulation at the pull-up node PU.

When one frame ends and before a next frame arrives refers to: after the shift register scans from the first row to the last row and before the shift register starts the repeated scan process again.

Here, when the clock signal terminal connected to the shift register in a G(n)-th stage is CLK, the clock signal terminal connected to the shift register in a G(n+1)-th stage is CLKB.

When signal of one frame is abnormal, the pull-up node PU cannot discharge, but before the arrival of the next frame of signal, the interference removing signal GLB (i.e. STV or CTR) is an active control signal first, thus the interference removing transistor M10 is turned on, so that the pull-down node PD is at a high level, so as to discharge the pull-up node PU before the clock signal CLK arrives, consequently, there is no erroneous output, product quality and reliability are higher with the fault-tolerant mechanism being added.

FIG. 5 is merely an implementation example of the present disclosure, and the present disclosure is not limited thereto.

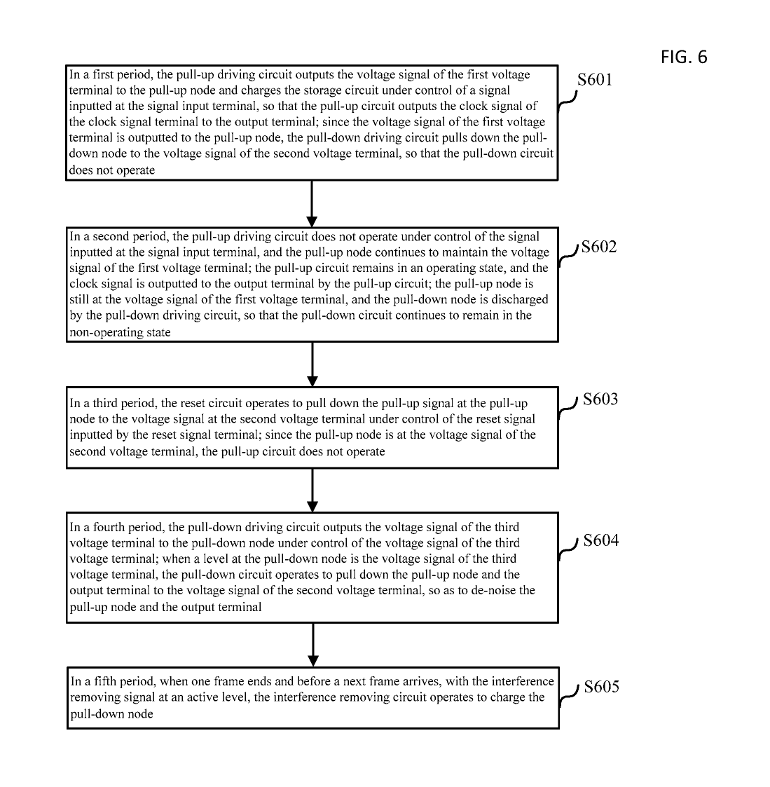

FIG. 6 shows a flow chart of a driving method for a shift register according to an embodiment of the present disclosure.

In a first period, the pull-up driving circuit outputs the voltage signal of the first voltage terminal to the pull-up node and charges the storage circuit under control of a signal inputted at the input signal terminal, so that the pull-up circuit outputs the clock signal of the clock signal terminal to the output terminal; since the voltage signal of the first voltage terminal is outputted to the pull-up node, the pull-down driving circuit pulls down the pull-down node to the voltage signal of the second voltage terminal, so that the pull-down circuit does not operate (S601).

In a second period, the pull-up driving circuit does not operate under control of the signal inputted at the input signal terminal, and the pull-up node continues to maintain the voltage signal of the first voltage terminal; the pull-up circuit remains in an operating state, and the clock signal is outputted to the output terminal by the pull-up circuit; the pull-up node is still at the voltage signal of the first voltage terminal, and the pull-down node is discharged by the pull-down driving circuit, so that the pull-down circuit continues to remain in the non-operating state (S602).

In a third period, the reset circuit operates to pull down the pull-up signal at the pull-up node to the voltage signal at the second voltage terminal under control of the reset signal inputted by the reset signal terminal; since the pull-up node is at the voltage signal of the second voltage terminal, the pull-up circuit does not operate (S603).

In a fourth period, the pull-down driving circuit outputs the voltage signal of the third voltage terminal to the pull-down node under control of the voltage signal of the third voltage terminal; when the pull-down node is at the voltage signal of the third voltage terminal, the pull-down circuit operates to pull down the pull-up node and the output terminal to the voltage signal of the second voltage terminal, so as to de-noise the pull-up node and the output terminal (S604).

In a fifth period, when one frame ends and before a next frame arrives, with the interference removing signal at an active level, the interference removing circuit operates to charge the pull-down node (S605).

The structure of the new shift register with the fault tolerance mechanism provided in the present disclosure not only considers the lifespan of the shift register and the related problems of reliability, but also has some tolerance mechanism for signal disorder.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

The foregoing is description of the present disclosure and should not be construed as limiting the present disclosure. Although several exemplary embodiments of the present disclosure have been described, those skilled in the art will readily appreciate that many modifications may be made to the exemplary embodiments without departing from the novel teachings and advantages of the present disclosure. Accordingly, all such modifications are intended to be included within the scope of the present disclosure as defined by the claims. It is to be understood that the foregoing is description of the present disclosure and should not be construed as limited to the particular embodiments disclosed herein, and modifications to the disclosed embodiments and other embodiments are intended to be included within the scope of the appended claims. The present disclosure is defined by the claims and their equivalents.

What is claimed is:

1. A shift register, comprising:
a pull-up driving circuit connected to an input signal terminal, a first voltage terminal and a pull-up node, and configured to output a voltage signal of the first voltage terminal to the pull-up node when an input signal of the input signal terminal is at an active input level;
a pull-up circuit connected to a clock signal terminal, the pull-up node and an output terminal, and configured to output a clock signal of the clock signal terminal to the output terminal when a pull-up signal of the pull-up node is at an active pull-up level;
a pull-down driving circuit connected to a second voltage terminal, a third voltage terminal, the pull-up node and a pull-down node, and configured to control a potential at the pull-down node;
a pull-down circuit connected to the second voltage terminal, the pull-down node, the pull-up node and the output terminal, and configured to pull down the output terminal and the pull-up node to a voltage signal of the second voltage terminal when a pull-down signal of the pull-down node is at an active pull-down level; and
an interference removing circuit connected to an interference removing signal terminal and the pull-down node, and configured to transmit an active interference removing signal to the pull-down node to charge the pull-down node when an interference removing signal outputted at the interference removing signal terminal is at an active control level.

2. The shift register of claim 1, wherein the interference removing circuit comprises an interference removing transistor,
a gate and a first electrode of the interference removing transistor are both connected to the interference removing signal terminal, and a second electrode of the interference removing transistor is connected to the pull-down node.

3. The shift register of claim 1, wherein the interference removing signal is an active control level signal after abnormity occurs to an output signal of the shift register and before a next frame signal arrives.

4. The shift register of claim 1, wherein the pull-up driving circuit comprises a pull-up driving transistor,
a gate of the pull-up driving transistor is connected to the input signal terminal, a first electrode of the pull-up driving transistor is connected to the first voltage terminal, and a second electrode of the pull-up driving transistor is connected to the pull-up node.

5. The shift register of claim 1, wherein the pull-up circuit comprises an output transistor,
a gate of the output transistor is connected to the pull-up node, a first electrode of the output transistor is connected to the clock signal terminal, and a second electrode of the output transistor is connected to the output terminal.

6. The shift register of claim 1, wherein the pull-down driving circuit comprises:
a first pull-down driving transistor, a gate of the first pull-down driving transistor being connected to a second electrode of a third pull-down driving transistor, a first electrode of the first pull-down driving transistor being connected to the third voltage terminal, and a second electrode of the first pull-down driving transistor being connected to the pull-down node;
a second pull-down driving transistor, a gate of the second pull-down driving transistor being connected to the pull-up node, a first electrode of the second pull-down driving transistor being connected to the pull-down node, and a second electrode of the second pull-down driving transistor being connected to the second voltage terminal;
the third pull-down driving transistor, a gate and a first electrode of the third pull-down driving transistor being connected to the third voltage terminal; and
a fourth pull-down driving transistor, a gate of the fourth pull-down driving transistor being connected to the pull-up node, a first electrode of the fourth pull-down driving transistor being connected to the second electrode of the third pull-down driving transistor, and a second electrode of the fourth pull-down driving transistor being connected to the second voltage terminal.

7. The shift register of claim 1, wherein the pull-down circuit comprises:
a node pull-down transistor, a gate of the node pull-down transistor being connected to the pull-down node, a first electrode of the node pull-down transistor being connected to the pull-up node, and a second electrode of the node pull-down transistor being connected to the second voltage terminal; and
an output pull-down transistor, a gate of the output pull-down transistor being connected to the pull-down node, a first electrode of the output pull-down transistor being connected to the output terminal, and a second electrode of the output pull-down transistor being connected to the second voltage terminal.

8. The shift register of claim 1, further comprising: a storage circuit,
a first terminal of the storage circuit being connected to the pull-up node and a second terminal of the storage circuit being connected to the output terminal, and the storage circuit being configured to be charged when the voltage signal of the first voltage terminal is passed to the pull-up node.

9. The shift register of claim 1, further comprising: a reset circuit connected to a reset signal terminal, the second voltage terminal and the pull-up node, and configured to pull down the pull-up node to the voltage signal of the second voltage terminal when a reset signal at the reset signal terminal is at an active control level.

10. The shift register of claim 9, wherein the reset circuit comprises:
a reset transistor, a gate of the reset transistor being connected to the reset signal terminal, a first electrode of the reset transistor being connected to the pull-up node, and a second electrode of the reset transistor being connected to the second voltage terminal.

11. The shift register of claim 1, wherein each of transistors in the shift register is an N-type transistor.

12. The shift register of claim 11, wherein the second voltage terminal is a low voltage terminal, the first voltage terminal and the third voltage terminal are a high voltage terminal each.

13. The shift register of claim 12, wherein the interference removing signal is one of a frame start signal and a control signal.

14. A gate driving circuit, comprising N cascaded shift registers as claimed in claim 1, N being a natural number,
wherein the input signal terminal of the shift register in a first stage is connected to a frame start signal terminal, and the reset signal terminal of the shift register in the first stage is connected to the output terminal of the shift register in a next stage,
the input signal terminal of the shift register in a last stage is connected to the output terminal of the shift register in a previous stage, the reset signal terminal of the shift register in the last stage is connected to the frame start signal terminal,
as for the shift register other than the shift register in the first stage and the shift register in the last stage, the input signal terminal thereof is connected to the output terminal of the shift register in a previous stage, and the reset signal thereof is connected to the output terminal of the shift register in a next stage,
in the gate driving circuit, a same interference removing signal is inputted to the interference removing signal terminal of the shift register in each stage.

15. The gate driving circuit of claim 14, wherein the interference removing circuit comprises an interference removing transistor,
a gate and a first electrode of the interference removing transistor are both connected to the interference removing signal terminal, and a second electrode of the interference removing transistor is connected to the pull-down node.

16. The gate driving circuit of claim 14, wherein the clock signal terminal of the shift register in an n-th stage receives a first clock signal, the clock signal terminal of the shift register in an (n+1)-th stage receives a second clock signal, n being an integer greater than zero and less than N.

17. The gate driving circuit of claim 15, wherein the interference removing signal is an active control level signal after abnormity occurs to an output signal of the shift register and before a next frame signal arrives.

18. A display device, comprising the gate driving circuit as claimed in claim 14.

19. A driving method for a shift register, the method comprising:
in a first period, the pull-up driving circuit outputs the voltage signal of the first voltage terminal to the pull-up node and charges the storage circuit under control of a signal inputted at the input signal terminal, so that the pull-up circuit outputs the clock signal of the clock signal terminal to the output terminal; since the voltage signal of the first voltage terminal is outputted to the pull-up node, the pull-down driving circuit pulls down the pull-down node to the voltage signal of the second voltage terminal, so that the pull-down circuit does not operate;
in a second period, the pull-up driving circuit does not operate under control of the signal inputted at the input signal terminal, and the pull-up node continues to maintain the voltage signal of the first voltage terminal; the pull-up circuit remains in an operating state, and the clock signal is outputted to the output terminal by the pull-up circuit; the pull-up node is still at the voltage signal of the first voltage terminal, and the pull-down node is discharged by the pull-down driving circuit, so that the pull-down circuit continues to remain in the non-operating state;
in a third period, the reset circuit operates to pull down the pull-up signal at the pull-up node to the voltage signal at the second voltage terminal under control of the reset signal inputted by the reset signal terminal; since the pull-up node is at the voltage signal of the second voltage terminal, the pull-up circuit does not operate;
in a fourth period, the pull-down driving circuit outputs the voltage signal of the third voltage terminal to the pull-down node under control of the voltage signal of the third voltage terminal; when a level at the pull-down node is the voltage signal of the third voltage terminal, the pull-down circuit operates to pull down the pull-up node and the output terminal to the voltage signal of the second voltage terminal, so as to de-noise the pull-up node and the output terminal; and
in a fifth period, when one frame ends and before a next frame arrives, with the interference removing signal at an active level, the interference removing circuit operates to charge the pull-down node.

20. The driving method of claim 18, wherein the second voltage terminal is a low voltage terminal; the first voltage terminal and the third voltage terminal are a high voltage terminal each.
